(19) United States
(12) Patent Application Publication
(10) Pub. No.: US 2025/0081655 A1
(43) Pub. Date: Mar. 6, 2025

(54) LIGHT-SENSITIVE MATRIX-ARRAY DETECTOR AND PROCESS FOR PRODUCING THE LIGHTSENSITIVE DETECTOR

(71) Applicant: TRIXELL, MOIRANS (FR)

(72) Inventors: Bruno COMMERE, MOIRANS (FR); Simon MARECAUX, MOIRANS (FR); Thibaut WIRTH, MOIRANS (FR); Mohamed ZEKHNINI, MOIRANS (FR); Thierry DUCOURANT, MOIRANS (FR)

(21) Appl. No.: 18/723,886

(22) PCT Filed: Dec. 27, 2022
(86) PCT No.: PCT/EP2022/087924

§ 371 Date: Jun. 25, 2024

(30) Foreign Application Priority Data
Dec. 28, 2021 (FR) FR2114586

(51) Int. Cl. H01L 27/146

(52) U.S. Cl. CPC H10F 39/809; H10F 39/018; H10F 39/811; H10F 39/813

(57) ABSTRACT

A matrix photosensitive detector organized in pixels and to a method for producing the detector, the detector comprising: a flat substrate having multiple interconnect levels connected to one another by through vias, a photodetector grouping together the pixels of the photosensitive detector, arranged on a first external face of the flat substrate and configured to bring about conversion of radiation to which the detector is sensitive into an electrical signal by each of the pixels, semiconductor microcircuits configured to drive and read out each of the pixels, the microcircuits being arranged facing each of the pixels or between adjacent pixels perpendicular to the substrate, each microcircuit being carried on a microsubstrate independent from the flat substrate of the photosensitive detector, the microcircuits being connected individually to the flat substrate at one of its interconnect levels.

### CROSS-REFERENCE TO RELATED APPLICATIONS

This application is a National Stage of International patent application PCT/EP2022/087924, filed on Dec. 27, 2022, which claims priority to foreign French patent application No. FR 2114586, filed on Dec. 28, 2021, the disclosures of which are incorporated by reference in their entireties.

### FIELD OF THE INVENTION

The invention relates to a photosensitive detector and to the method for producing it. The invention is of particular use for producing a photosensitive detector used to create visible images. The invention is not limited to producing this type of detector. The invention may be implemented in order to produce a detector for creating pressure or temperature maps or else two-dimensional representations of chemical or electrical potentials. These maps or representations form images of physical quantities.

### BACKGROUND

The invention may be applied notably to the production of active-matrix detectors used for example for detection purposes in imaging devices employing ionizing radiation, for example X-rays or gamma rays.

In a matrix detector, a pixel represents the elementary sensitive element of the detector. Each pixel converts a physical phenomenon to which it is subjected into an electrical signal. The electrical signals coming from the various pixels are collected in a matrix readout phase and then digitized so as to be able to be processed and stored in order to form an image. The pixels are formed of a zone sensitive to the physical phenomenon and deliver for example a current of electric charges. The physical phenomenon may be electromagnetic radiation carrying a photon flux, and the invention will be explained below by way of this type of radiation, and the charge current depends on the photon flux received by the sensitive zone. General application to any type of matrix detector will be easy.

A matrix image detector comprises row conductors, each connecting the pixels of one and the same row, and column conductors, each connecting the pixels of one and the same column. The column conductors are connected to conversion circuits, which are generally arranged on an edge of the matrix, which may be called the “column base”. It goes without saying that the names “rows” and “columns” are purely conventional and may be swapped.

Each pixel generally comprises a photosensitive component, or photodetector, which may for example be a photodiode, a photoresistor or a phototransistor. There are large photosensitive matrices that may have several million pixels organized into rows and columns. Each pixel furthermore comprises an electronic circuit comprising at least one actuator. The electronic circuit may furthermore comprise other switches, capacitors, resistors, downstream of which the actuator is situated. The assembly consisting of the photosensitive component and the electronic circuit makes it possible to generate electrical signals and to collect them. The electronic circuit generally makes it possible to reset the signal collected in each pixel after a transfer in order to read out the pixel. The role of the actuator is that of transferring or copying, into a column conductor, the signals collected by the electronic circuit on the basis of the information received from the photosensitive component. This transfer is carried out when the actuator receives the instruction to do so from a row conductor. The output of the actuator corresponds to the output of the pixel.

X-ray detectors are subject to a dimensional constraint. Indeed, there are no simple means for deflecting this type of radiation. The detector therefore has to have the dimensions of the image to be produced. For example, in medical radiology, a detector may have a side length of more than 400 mm. It is not easy to produce detectors having such dimensions.

At present, there are two major families of X-ray matrix detectors. The first family uses materials such as silicon in the amorphous, polycrystalline or microcrystalline state. These materials are deposited in thin layers on substrates made of glass or polyimide, for example. A second family uses monocrystalline materials. The second family makes it possible to achieve much better performance than the first family. On the other hand, the second family is limited in terms of dimensions due to the silicon substrates that are used. In order to produce large detectors in the second family, it is necessary to piece together multiple substrates on which parts of the detector are produced.

Moreover, in both families of detectors, the reject rate may be high during manufacture of the detector. Indeed, the greater the number of pixels, the more the risk of at least one pixel being defective increases. It is possible to accept a few isolated pixels being defective by virtue of image correction, but this remains an imperfect workaround.

One of the important parameters that leads to a high reject rate lies in the complexity of the electronic circuits associated with each pixel. In practice, the more the complexity of the electronic circuits increases, the more the reject rate increases.

### SUMMARY OF THE INVENTION

The invention aims to overcome all or some of the problems mentioned above by proposing a matrix photosensitive detector in which the electronic circuits providing at least the functions of driving and reading out each of the pixels are implemented separately each on their own substrate, thereby making it possible to use substrates with different technologies for the electronic circuits and for the detector itself. The invention also makes it possible to individually test each electronic circuit before it is transferred to the substrate of the detector. This makes it possible to improve the reliability of the detectors.

To this end, one subject of the invention is a matrix photosensitive detector organized into pixels, comprising:
a flat substrate having multiple interconnect levels connected to one another by through vias,
a photodetector grouping together the pixels of the photosensitive detector, arranged on a first external face of the flat substrate and configured to bring about conversion of radiation to which the detector is sensitive into an electrical signal by each of the pixels,
semiconductor microcircuits configured to drive and read out each of the pixels, the microcircuits being arranged facing each of the pixels or between adjacent pixels perpendicular to the substrate, each microcircuit being carried on a microsubstrate independent from the flat substrate of the photosensitive detector, the microcircuits being connected individually to the flat substrate at one of its interconnect levels.

Advantageously, the flat substrate has a second external face and connection pads arranged on the second external face and connected to the interconnect levels, the microcircuits being arranged on the second external face and being connected to the connection pads.

Advantageously, the flat substrate has connection pads arranged on the first external face and connected to the interconnect levels, the connection pads of the first external face each forming an individual electrode of one of the pixels.

The photodetector may be in the form of a continuous layer arranged on the connection pads of the first external face. As an alternative, the photodetector is formed of discrete photodetection components each forming one of the pixels.

The photodetection components may be embedded in the flat substrate.

The microcircuits may be arranged in the flat substrate.

The microcircuits may be common to multiple adjacent pixels.

Another subject of the invention is a method for producing a photosensitive detector, consisting in:
producing a flat substrate having multiple interconnect levels connected to one another by through vias,
producing semiconductor microcircuits configured to drive and read out each of the pixels, each on a microsubstrate independent from the flat substrate of the photosensitive detector,
transferring each microcircuit to the flat substrate by individually connecting it to one of the interconnect levels.

Advantageously, the method consists in testing the microcircuits before transferring them to the flat substrate of the photosensitive detector.

### BRIEF DESCRIPTION OF THE DRAWINGS

The invention will be better understood and other advantages will become apparent on reading the detailed description of an embodiment given by way of example, which description is illustrated by the appended drawing, in which:

FIG. 1 schematically shows multiple interconnect levels of a substrate of a photosensitive detector according to the invention;

FIGS. 2a and 2b show a first variant of a first embodiment of a photosensitive detector according to the invention;

FIGS. 3a and 3b show a second variant of the first embodiment;

FIGS. 4a and 4b show two variants of a second embodiment of a photosensitive detector according to the invention;

FIGS. 5a and 5b show a variant in which a microcircuit is common to multiple contiguous pixels of the detector;

FIGS. 6a and 6b show a variant in which a microcircuit is integrated into a substrate of a photosensitive detector according to the invention.

For the sake of clarity, the same elements will bear the same reference signs in the various figures.

### DETAILED DESCRIPTION

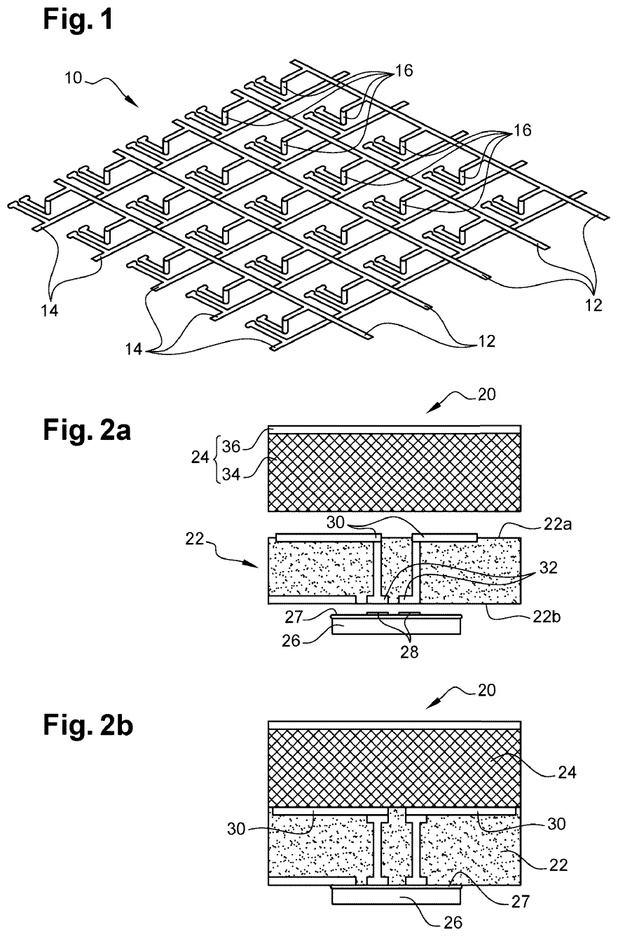

The invention relates to a photosensitive matrix detector able to detect light radiation reaching a detection zone. The photosensitive detector comprises a matrix of photosensitive elements or detection pixels distributed over the detection zone. FIG. 1 schematically shows a substrate 10 of a photosensitive detector according to the invention. The substrate 10 is in the form of a plate having at least the surface area of the detection zone. The photosensitive elements will be described later on. The substrate performs two main functions: mechanical support and connecting the photosensitive elements. To provide the mechanical support function, the substrate 10 is for example made from a plate of glass, organic material, any other material used to produce printed circuit boards, etc. Any other type of material may be used within the scope of the invention. The material that is selected may for example allow the detector to be flexible. The photosensitive elements generally require at least two types of connection, one for driving and the other for reading out the photosensitive elements. Other types of connection may also be used, such as power supplies, for example. The photosensitive elements are thus connected, through the substrate, to drive modules and readout circuits that may be located outside the detection zone. For example, when the detection zone is rectangular in shape, the drive modules may be located on one side of the rectangular shape, and the readout circuits on an adjacent side. To provide the function of connecting the photosensitive elements, the substrate may then comprise row conductors for connecting the drive modules to the photosensitive elements and column conductors for connecting the readout circuits to the photosensitive elements. It goes without saying that the names “rows” and “columns” are purely conventional and may be swapped. In the substrate 10, the row conductors and column conductors must cross one another without being in contact. To this end, the substrate 10 comprises two interconnect levels, one comprising the row conductors 12 and the other comprising the column conductors 14. The photosensitive elements are arranged on one of the faces of the substrate 10, and through vias 16 provide the connections between the conductors 12 and/or 14 and the photosensitive elements. In practice, the substrate 10 may comprise more than two interconnect levels, depending on the connection needs of the various photosensitive elements. The interconnect levels may be internal or arranged on external faces of the substrate 10.

The substrate 10 shown in FIG. 1 comprises only a single row conductor and a single column conductor associated with each photosensitive element. It is of course possible to provide multiple row conductors and/or multiple column conductors associated with each photosensitive element.

FIGS. 2a and 2b illustrate, in partial section, in a plane perpendicular to the plane of the substrate, a first variant of a first embodiment of a photosensitive detector 20. FIG. 2a shows, spaced apart from one another, three components of the detector 20: a substrate 22 as illustrated in FIG. 1, a photodetector 24 and a microcircuit 26 carried by a microsubstrate 27 independent from the substrate 22. Independent is understood to mean that it may be manufactured separately. The photodetector 24 is arranged facing a first face 22a of the substrate 22, and the microcircuit 26 is arranged facing a second face 22b of the substrate 22. The second face 22b is opposite the first face 22a. The three components of the detector 20 may be produced separately and then assembled to form the photosensitive detector 20 as shown in FIG. 2b, in which the photodetector 24 is arranged on the face 22a and in which the microcircuit 26 is arranged on the face 22b.

The substrate 22 comprises conductive pads 30 on its face 22a and conductive pads 32 on its face 22b. The conductive pads 30 and 32 are connected to the various interconnect levels, not shown in FIGS. 2a and 2b. Only a few vias 16 are shown by way of example. The interconnect levels may be arranged on internal layers or on the external faces 22a and 22b of the substrate 22. The microcircuit 26 is for example connected to the interconnect levels of the substrate 22 through pads 28 that are present on the microsubstrate 27 and come into contact with the pads 32 of the substrate 22.

A single microcircuit 26 is shown in FIGS. 2a and 2b. It is common to two adjacent photosensitive elements here, and therefore connected to two pads 30. As an alternative, a microcircuit 26 may be associated with just one photosensitive element or with more than two photosensitive elements, four as illustrated later on with the aid of FIGS. 5a and 5b. The number of microcircuits is proportional to the number of photosensitive elements. The microcircuits comprise semiconductors and are configured to at least drive and read out each of the photosensitive elements. As indicated in the introduction, the operation of a photosensitive element generally requires at least one electronic switch for reading out the photosensitive element by transferring, when it is closed, the signal accumulated for example in a photodiode in the form of charge to a column conductor. The switch is controlled by way of a row conductor. In the prior art, the switch and the photodiode are produced using microelectronics techniques, directly on the substrate. Some photosensitive elements use more complex circuits, for example with three transistors. There is a transistor performing the function of a readout switch, and this has added to it a follower transistor arranged between the photodiode and the readout transistor along with a reset transistor for applying a fixed potential to the photodiode. Controlling the reset transistor requires it to be connected to a particular row conductor. In the prior art, where the transistors are produced directly on the substrate of the detector, it is barely possible to produce more complex control circuits because the need to associate a circuit with each photodiode exhibits a reliability risk for a detector having several million pixels. It has been envisaged to produce complex circuits notably in detectors produced using what is known as CMOS or IGZO technology. CMOS on silicon technology uses metal-oxide-semiconductor field-effect transistors by combining complementary n-type and p-type components. This technology is known by its acronym CMOS: complementary metal oxide semiconductor. IGZO technology uses indium-gallium-zinc oxide-based semiconductors and is known by its acronym IGZO: indium gallium zinc oxide.

The invention proposes to dissociate the photosensitive element itself, for example formed by a photodiode, a photoconductor, etc. and the circuit associated therewith, and produce the circuit separately on its own substrate, independent from the substrate of the detector. Since this circuit is small, for example of the order of a few μm, it is called a microcircuit. The size of the microcircuits should be considered in relation to that of the detector itself. The substrate 22 of the detector may for its part have a surface area close to that of the complete detector. In an X-ray radiology application, a conventional detector format is 430 mm×430 mm. The microcircuits 26, since they are produced separately from the main substrate of the detector, may be tested individually before being transferred to the substrate 22. Thus, only microcircuits that have successfully passed the individual test step are transferred to the substrate of the detector. The improved reliability of the microcircuits makes it possible to envisage circuits that are much more complex than those mentioned above with one or three transistors. It is possible notably to implement circuits integrating complex counting, digitization, etc, functions. Another advantage of producing the substrate of the detector and the microcircuits separately is that of enabling the use of different manufacturing methods. It is for example possible to produce microcircuits using high-performance semiconductor materials whose production temperatures are very significantly higher, typically in the range of 500 to 1000° C. By way of example, CMOS technologies, already mentioned above, make it possible to produce complex and high-performance circuits but require production temperatures higher than the limits able to be tolerated by substrates based on glass or organic materials.

In the example shown in FIGS. 2a and 2b, the substrate 22 comprises conductive pads 30 on its face 22a, the surface of each of the conductive pads forming the surface of a photosensitive element. More precisely, the pads 30 form an individual electrode of each of the photosensitive elements. In other words, the detector comprises as many photosensitive elements as there are pads 30. The photosensitive detector 20 is a matrix detector organized into pixels. In this example, the surface of each pad 30 forms the photosensitive surface of a pixel. The photodetector 24 groups together the pixels of the photosensitive detector. The microcircuits 26 are arranged facing each of the pixels perpendicular to the substrate 22, and therefore facing these external faces 22a and 22b. In practice, the substrate 22 may be flexible and have a slight curvature. The perpendicularity is then defined locally at each pixel with respect to a plane tangent to the curvature of the substrate 22.

By arranging the microcircuits 26 facing each of the pixels, it is possible to minimize the length of the connections between the microcircuits 26 and the pixels. This minimization makes it possible to reduce electromagnetic sensitivity to disturbances coming from the environment. Moreover, use is advantageously made only of vias 16 perpendicular to the plane in which the substrate 22 mainly extends. The connections between the microcircuits 26 and the pixels are then all identical for all of the pixels of the photodetector 24. Thus, if electromagnetic disturbances disturb the connections, these disturbances will be substantially identical for all of the pixels of the photodetector 24.

In practice, for a detector used in X-ray radiology, the photosensitive elements each have for example a square surface with a side length of the order of 50 to 200 μm depending on the applications envisaged. The pads 30 therefore have this square shape and are spaced apart by 5 to 10 μm. It is advantageous to reduce the distance between the photosensitive elements as far as possible in order to maximize the surface occupied by the photosensitive elements. This makes it possible to maximize the sensitivity of the detector 20. In this embodiment, it is advantageous not to use the external face 22a to route thereon row or column conductors between the pads 30. The row and column conductors are then routed on the face 22b and in layers internal to the substrate 22.

In the example shown in FIGS. 2a and 2b, the photodetector 24 comprises a layer that directly converts the incident radiation that it is desired to detect. In X-ray radiology, it is possible to use materials based on selenium, cadmium telluride (CdTe), materials from the family of perovskites, etc. to bring about the direct conversion of X-ray photons into electric charges diffusing onto the electrodes formed by the pads 30. These materials may be deposited in the form of a layer 34 covering the face 22a. The layer 34 may be either continuous, if the lateral diffusion is low enough, or delimited into pixels. Depositing a continuous layer 34 has the advantage of not having to worry about the lateral positioning of the layer facing each of the pads 30. The layer 34 may be produced directly on the substrate 22 if the method for depositing the layer 34 is compatible with the substrate 22, in particular in terms of temperature. As an alternative, it is possible to produce the layer 34 on a dedicated substrate 36 forming a second electrode for the photodetector 24. The assembly formed by the substrate 36 and the layer 34 forming the photodetector is then transferred to the substrate 22.

To facilitate positioning of a discontinuous-layer photodetector, that is to say one delimited into pixels or into groups of pixels, on the substrate 22, it is possible to produce the discontinuous layer and electrodes forming the detection surface of each of the pixels on the substrate 36. These electrodes are then put into contact with pads 30 with a smaller surface area than that of the electrodes of the photodetector. The smaller the pads 30, the greater the positioning tolerance.

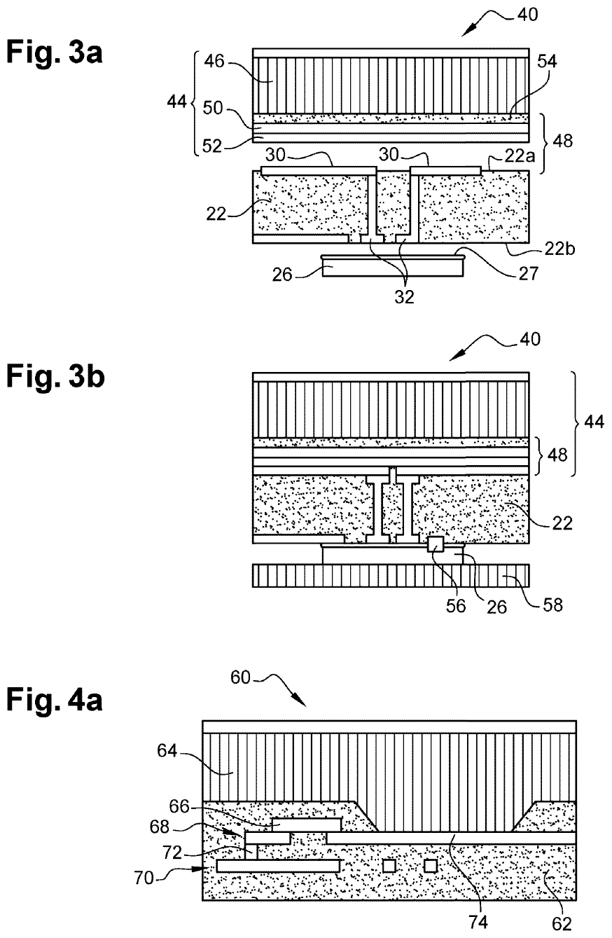

In the first variant, the detection is referred to as “direct”. In other words, the incident radiation to be detected by the detector is converted directly into an electrical signal in the photodetector 24. A second variant, referred to as “indirect” detection and illustrated in FIGS. 3a and 3b, shows a photosensitive detector 40. The substrate 22 and the microcircuits 26 arranged facing a second face 22b of the substrate 22 may be seen therein. The photodetector 24 from the first variant is replaced by a photodetector 44 formed of a scintillator 46 and a photodetection component, such as for example a photodiode 48. Like for the first variant, FIG. 3a shows the substrate 22, a microcircuit 26 and a photodetector 44 spaced apart from one another. FIG. 3b shows these same elements in the assembled state.

The incident radiation passes through the scintillator 46, converting its photons into other photons in a wavelength band adapted to the photodiode 48. This second variant is well suited to the detection of X-rays, in which the scintillator converts the X-ray photons into visible photons. Various materials may be used to produce the scintillator, such as for example thallium-doped cesium iodide or gadolinium oxysulfide, known by the abbreviations GOS or GADDOX, etc.

The photodetection component here is a photodiode 48. As an alternative, it is possible to use any type of component able to convert photons emitted by the scintillator into an electrical signal. Generally speaking, a photodiode comprises two electrodes separated by a photodetector layer able to transform the photons that it receives into an electrical signal. As before, one of the electrodes may be formed by a pad 30 belonging to the substrate 22. The photodiode 48 also comprises an electrode 50 and a photodetector layer 52. The electrode 50 here is transparent to the photons emitted by the scintillator 46. The electrode 50 is for example made of tin oxide, indium-tin oxide, etc. Since this type of electrode may have a high resistivity, it is possible to add a metal mesh 54 in order to reduce the impedance of the surface of the electrode 50.

FIG. 3a shows an electrode 50 and a photodetector layer 52 that are continuous. Like for the first variant, it is possible to produce the electrode 50 and the photodetector layer 52 discontinuously, that is to say delimited into pixels or into groups of pixels. As before, in the case of discontinuous layers, the electrode 30 may be produced directly on the photodetector layer 52. The assembly formed by the scintillator 46 and the photodiode 48 comprising these two electrodes 30 and 50 is attached to pads of the face 22a of the substrate 22.

FIG. 3b shows the substrate 22, a microcircuit 26 and a photodetector 44 in the assembled state. In addition to the circuits for driving and reading out the pixel associated therewith, the microcircuit 26 may optionally comprise a light-emitting diode 56 for emitting a flash of light in the direction of the photodiode 48 in order to saturate it. This type of illumination may take place after the photodiode 48 has been read out in order to avoid any remanence. When a light-emitting diode 56 is used, the electrode 30 and the substrate 22 are at least partially transparent to the light radiation emitted by the light-emitting diode 56. Other components, such as for example thermal or mechanical sensors, may also be transferred in addition to or instead of the light-emitting diode 56.

Still optionally, the detector 40 may comprise a second scintillator 58 covering the microcircuits 26 over the entire detection surface of the detector 40. The scintillator 58 makes it possible to recover X-ray photons that were not converted in the scintillator 46 in order to return their energy in the form of visible photons to the photodiode 48, thus improving the sensitivity of the detector or making it possible to produce images in dual-energy mode.

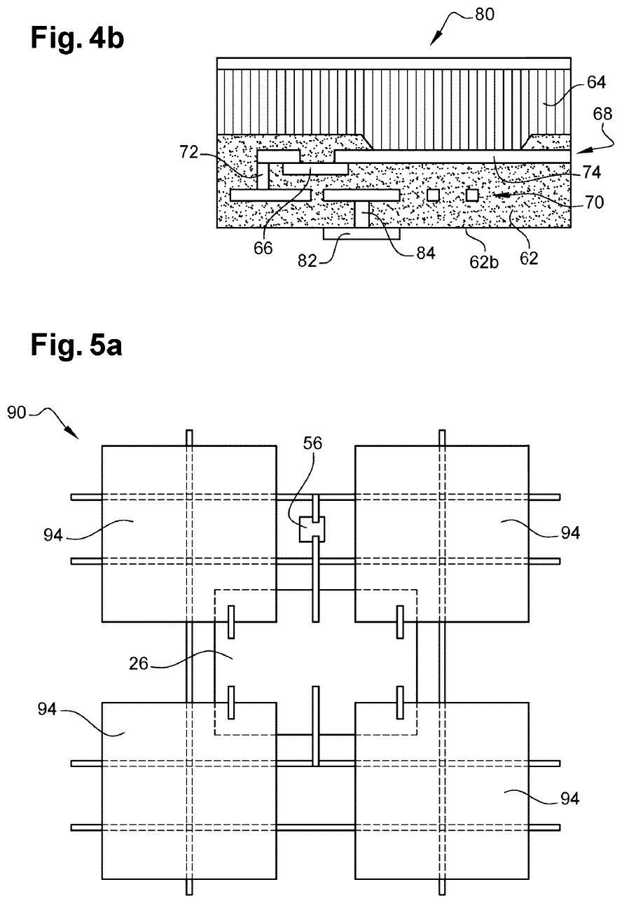

FIGS. 4a and 4b illustrate two variants of a second embodiment of a photosensitive detector according to the invention. In these two variants, the microcircuits are arranged in the substrate. More precisely, the microcircuits, each produced on their independent substrate, are transferred to the substrate of the detector.

FIG. 4a shows, in section, the detector 60 comprising a substrate 62, a photodetector 64 and multiple microcircuits 66, one of which is shown in FIG. 4a. The substrate 62 comprises for example two interconnect levels 68 and 70 connected by vias 72, one of which is shown in FIG. 4a. The interconnect levels 68 and 70 are embedded in a dielectric material that is partially perforated so as to reveal a pad 74 in the interconnect level 68. The pad 72 performs the same function as the pad 30 shown in FIGS. 2a and 2b. The photodetector 64 is in contact with the pad 74. The surface of each pad 74 forms the photosensitive surface of a pixel. The microcircuits 66 are arranged between two adjacent pixels.

FIG. 4b shows, in section, a detector 80 in which the substrate 62 and its two interconnect levels 68 and 70 are connected by vias 72. The pad 74 is located in the interconnect level 68 and forms the detection surface of a pixel of the detector 80. In the detector 60 illustrated in FIG. 4a, the microcircuit 66 is located on one face of the interconnect level 68, and in the detector 80 illustrated in FIG. 4b, the microcircuit 66 is located on an opposite face of the interconnect level 68. In FIG. 4b, the microcircuits 66 are also arranged between two adjacent pixels. The arrangement of the detector 80 makes it possible, if needed, to arrange the microcircuits 66 partly facing the pads 74 and therefore facing the pixels of the detector 80. In addition, if needed, it is possible to arrange a pad 82 on the face 32b of the substrate 62. The pad 82 is connected to the interconnect level 70 through a via 84. The pad 82 performs the same function as the pad 32 and makes it possible to connect another microcircuit thereto if the detector so requires.

More generally, the detectors 60 and 80 may be equipped with scintillators 46 and with a photodetection component, such as for example a photodiode 48 instead of the photodetector 64. The detectors 60 and 80 may comprise, associated with each pixel, one or more microcircuits arranged inside the substrate 62 of the detector and/or on one of its external faces.

FIGS. 5a and 5b show, in a front-on view for FIG. 5a and in section for FIG. 5b, a variant of a detector 90 according to the invention comprising a substrate 92 as illustrated in FIG. 1, a microcircuit 26, a light-emitting diode 56, which is produced separately from the microcircuit 26 here, along with a photodetector produced in two parts: a scintillator 46 and a matrix of photodetection components, such as for example a matrix of photodiodes 94. The matrix of photodetection components may be produced on a separate substrate 96 and then transferred to the interconnect substrate 92 or may form part of the interconnect substrate. As before, each photodiode 94 comprises two electrodes 96 and 98 each connected to one of the interconnect levels by way of vias. The photodiodes 94 may for example be made of amorphous silicon or with an organic semiconductor material.

In the example shown, the microcircuit 26 is common to four photodiodes 94. The microcircuit 26 is arranged partially facing the four photodiodes 94, such that the vias connecting the microcircuit 26 to the various photodiodes 94 extend mainly perpendicular to the plane of the interconnect substrate 92.

Other components, such as for example thermal or mechanical sensors, may also be transferred in addition to or instead of the light-emitting diode 56. These other components may be individually associated with each pixel or with each group of pixels, for example with four pixels, like the microcircuits 26.

Pooling a microcircuit 26 common to multiple contiguous pixels may of course be applied to all of the embodiments of the invention.

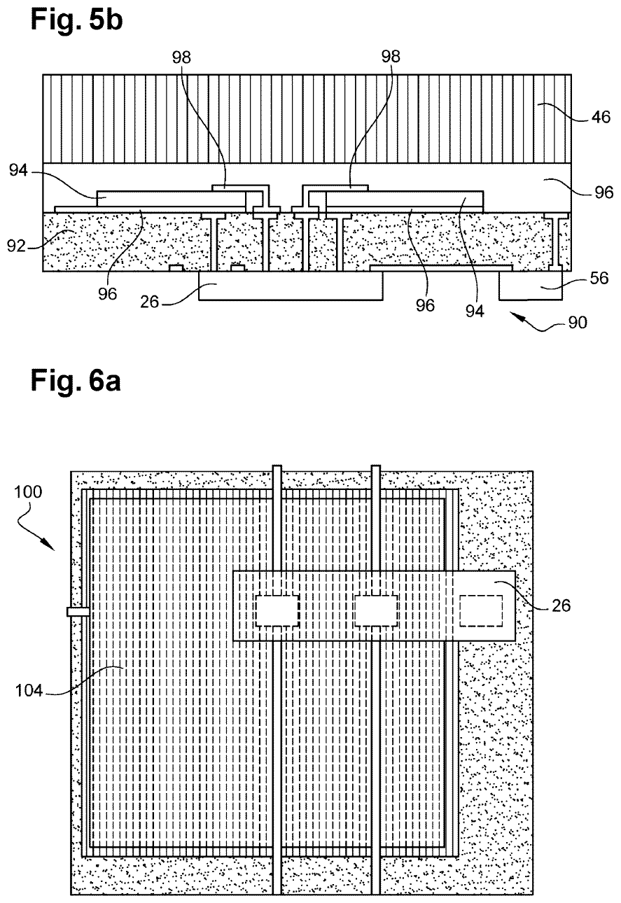

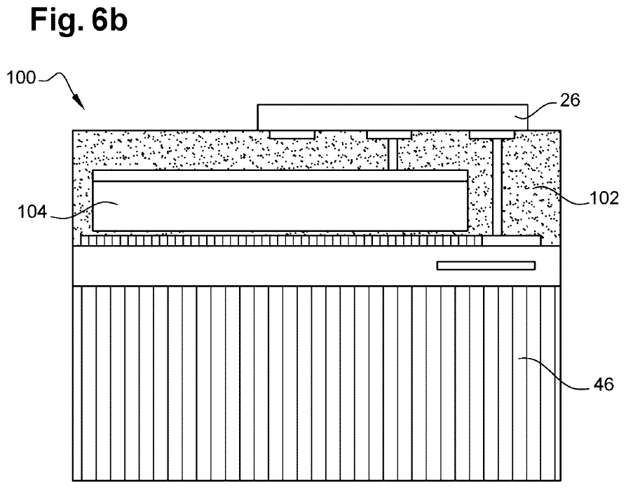

FIGS. 6a and 6b show, in a front-on view for FIG. 6a and in section for FIG. 6b, a variant of a detector 100 according to the invention comprising a substrate 102 as illustrated in FIG. 1, multiple microcircuits 26, one of which is shown, a matrix of photodiodes 104 and a scintillator 46. Unlike the detector 90, in the detector 100, the photodiodes 104, or more generally the photodetection components, are integrated into the substrate 102.

In the detector 100 shown in FIGS. 6a and 6b, the microcircuit 26 is associated with just one photodiode 104. It is also possible to pool the microcircuit 26 by associating it with multiple adjacent photodiodes 104.

The matrix of photodetection components is produced discontinuously in the detector 90 shown in FIGS. 5a and 5b and in the detector 100 shown in FIGS. 6a and 6b. It is possible to use multiple manufacturing methods for the photodetection components. Mention may be made, by way of example, of photolithography methods commonly used for matrices of photodetection components made of amorphous silicon on a glass-based substrate. It is also possible to use techniques of printing conductive inks and organic semiconductor materials.

1. A matrix photosensitive detector organized into pixels, comprising:
a flat substrate having multiple interconnect levels connected to one another by through vias,
a photodetector grouping together the pixels of the photosensitive detector, arranged on a first external face of the flat substrate and configured to bring about conversion of radiation to which the detector is sensitive into an electrical signal by each of the pixels,
semiconductor microcircuits configured to drive and read out each of the pixels, the microcircuits being arranged facing each of the pixels or between adjacent pixels perpendicular to the substrate, each microcircuit being carried on a microsubstrate independent from the flat substrate of the photosensitive detector, the microcircuits being connected individually to the flat substrate at one of its interconnect levels.

2. The photosensitive detector as claimed in claim 1, wherein the flat substrate has a second external face and connection pads arranged on the second external face and connected to the interconnect levels, and wherein the microcircuits are arranged on the second external face and are connected to the connection pads.

3. The device as claimed in claim 2, wherein the flat substrate has connection pads arranged on the first external face and connected to the interconnect levels, the connection pads of the first external face each forming an individual electrode of one of the pixels.

4. The device as claimed in claim 3, wherein the photodetector is in the form of a continuous layer arranged on the connection pads of the first outer face.

5. The device as claimed in claim 3, wherein the photodetector is formed of discrete photodetection components each forming one of the pixels.

6. The device as claimed in claim 4, wherein the photodetection components are embedded in the flat substrate.

7. The photosensitive detector as claimed in claim 1, wherein the microcircuits are arranged in the flat substrate.

8. The device as claimed in claim 1, wherein the microcircuits are common to multiple adjacent pixels.

9. The device as claimed in claim 1, wherein the microcircuits are connected to the pixels of the photosensitive detector only by way of vias perpendicular to a plane in which the flat substrate mainly extends.

10. A method for producing a photosensitive detector as claimed in claim 1, comprising the following steps:
producing a flat substrate having multiple interconnect levels connected to one another by through vias,
producing semiconductor microcircuits configured to drive and read out each of the pixels, each on a microsubstrate independent from the flat substrate of the photosensitive detector,
transferring each microcircuit to the flat substrate by individually connecting it to one of the interconnect levels.

11. The method as claimed in claim 10, furthermore comprising a step of testing the microcircuits before transferring them to the flat substrate of the photosensitive detector.
